(19) United States
(12) Patent Application Publication
(10) Pub. No.: US 2015/0107886 A1
(43) Pub. Date: Apr. 23, 2015

(54) INSULATING SUBSTRATE FOR PRINTED CIRCUIT BOARD AND PRINTED CIRCUIT BOARD

(71) Applicant: SAMSUNG ELECTRO-MECHANICS CO., LTD., Suwon (KR)

(72) Inventors: Yong Hwan KIM, Sejong (KR); Jung Hoon Jang, Sejong (KR)

(73) Assignee: SAMSUNG ELECTRO-MECHANICS CO., LTD., Suwon (KR)

(21) Appl. No.: 14/509,249

(22) Filed: Oct. 8, 2014

(30) Foreign Application Priority Data
Oct. 22, 2013 (KR) 10-2013-0126052

(51) Int. Cl. H05K 1/03; H05K 1/11

(52) U.S. Cl. CPC H05K 1/036; H05K 1/0366; H05K 1/115; H05K 2201/029
USPC 174/258; 428/212

(57) ABSTRACT

Disclosed herein are an insulating substrate for a printed circuit board and a printed circuit board, and more particularly, an insulating substrate for a printed circuit board and a printed circuit board capable of improving fill plating property of an inner via hole.

The insulating substrate for a printed circuit board includes: an electrical insulating resin; and a plurality of reinforcement materials formed in the electrical insulating resin, wherein the plurality of reinforcement materials are configured so that one or more reinforcement materials are formed to be symmetrical with each other at each of the upper and lower portions based on a central reinforcement material formed at a central portion in the electrical insulating resin, and a thickness of the central reinforcement material is thicker than those of the remaining other reinforcement materials.

### CROSS REFERENCE(S) TO RELATED APPLICATIONS

This application claims the foreign priority benefit under 35 U.S.C. Section 119 of Korean Patent Application Serial No. 10-2013-0126052, entitled “Insulating Substrate for Printed Circuit Board and Printed Circuit Board” filed on Oct. 22, 2013, which is hereby incorporated by reference in its entirety into this application.

### BACKGROUND OF THE INVENTION

1. Technical Field

The present invention relates to an insulating substrate for a printed circuit board and a printed circuit board, and more particularly, to an insulating substrate for a printed circuit board capable of improving fill plating property of an inner via hole (IVH) and a printed circuit board.

2. Description of the Related Art

A printed circuit board is emerging as an essential component in almost every electronic industry related field including home appliances such as a TV, a camera, a VCR, and the like as well as information devices such as a computer, a portable terminal and the like.

This printed circuit board includes a plurality circuit layers and has a via formed therein, where the via electrically connects between layers in order to improve electrical characteristics and a degree of freedom of a design. In this case, the via may be formed by forming a hole in an insulating substrate using laser and then plating inner walls of the hole.

Particularly, in a case of an inner via hole (IVH) formed on an inner layer of the insulating substrate, recently, the IVH is machined in a shape of sandglass (janggu) as shown in FIG. 1, that is, a shape in which a center portion has a small diameter and upper and lower portions have a large diameter. This is the reason that in the case of the shape of sandglass as mentioned above, a bridge for plating fill development may be secured to thereby finally improve fill plating property of the inner via hole.

This sandglass shape may be machined by drilling machining, laser machining, or the like using a CNC device. Particularly, in the case in which the laser machining is used, laser using CO₂, or the like may be used.

However, even though the same CO₂ laser machining conditions are used, the inner via hole having a shape as shown in FIG. 2 rather than the sandglass shape may be formed depending on a position, a thickness deviation, and the like of a reinforcement material of the machined insulating substrate. In a case of the inner via hole having this shape, as shown in FIG. 3, fill plating defects such as a dimple 10, a void 20, and the like may be caused.

Therefore, in a case of forming the inner via hole using the laser, or the like, above all things, there is need for development of an insulating substrate and a printed circuit board including the same capable of further improving fill plating property of the inner via hole by allowing the inner via hole having the sandglass shape to be naturally formed by adjustment of the formed position and the thickness deviation of the reinforcement material, and the like.

### SUMMARY OF THE INVENTION

An object of the present invention is to provide an insulating substrate for a printed circuit board capable of further improving fill plating property of an inner via hole and a printed circuit board.

According to an exemplary embodiment of the present invention, there is provided an insulating substrate for a printed circuit board, the insulating substrate including: an electrical insulating resin; and a plurality of reinforcement materials formed in the electrical insulating resin, wherein the plurality of reinforcement materials are configured so that one or more reinforcement materials are formed to be symmetrical with each other at each of the upper and lower portions based on a central reinforcement material formed at a central portion in the electrical insulating resin, and a thickness of the central reinforcement material is thicker than those of the remaining other reinforcement materials.

The thickness of the central reinforcement material may be thicker by 10 μm to 30 μm than those of the remaining other reinforcement materials.

Each of the plurality of reinforcement materials may be at least one selected from a group consisting of paper, glass fiber, glass nonwoven fabric, aramid fiber, liquid crystal polymer fiber, liquid crystal polymer nonwoven fabric, and hybrid fiber.

The glass fiber may be formed by twisting glass filaments including silica to thereby form yarns and weaving the yarns.

The glass filament of the central reinforcement material may have a diameter larger by 2 μm to 5 μm than those of the glass filaments of the remaining other reinforcement materials.

The plurality of reinforcement materials may be formed in three-layers of the central reinforcement material, an upper reinforcement material formed at an upper portion of the central reinforcement material, and a lower reinforcement material formed at a lower portion of the central reinforcement material, and the thickness of the central reinforcement material may be thicker than those of the upper reinforcement material and the lower reinforcement material.

The thickness of the central reinforcement material may be thicker by 10 μm to 30 μm than those of the upper reinforcement material and the lower reinforcement material.

Each of the central reinforcement material, the upper reinforcement material, and the lower reinforcement material may be at least one selected from a group consisting of paper, glass fiber, glass nonwoven fabric, aramid fiber, liquid crystal polymer fiber, liquid crystal polymer nonwoven fabric, and hybrid fiber.

The glass fiber may be formed by twisting glass filaments including silica to thereby form yarns and weaving the yarns.

The glass filament of the central reinforcement material may have a diameter larger by 2 μm to 5 μm than those of the glass filaments of the upper reinforcement material and the lower reinforcement material.

According to another exemplary embodiment of the present invention, there is provided a printed circuit board, including: an insulating substrate; and a via penetrating through the insulating substrate, wherein the insulating substrate includes: an electrical insulating resin; and a plurality of reinforcement materials formed in the electrical insulating resin, wherein the plurality of reinforcement materials are configured so that one or more reinforcement materials are formed to be symmetrical with each other at each of the upper and lower portions based on a central reinforcement material formed at a central portion in the electrical insulating resin, and a thickness of the central reinforcement material is thicker than those of the remaining other reinforcement materials.

The thickness of the central reinforcement material may be thicker by 10 μm to 30 μm than those of the remaining other reinforcement materials.

Each of the plurality of reinforcement materials may be at least one selected from a group consisting of paper, glass fiber, glass nonwoven fabric, aramid fiber, liquid crystal polymer fiber, liquid crystal polymer nonwoven fabric, and hybrid fiber.

The glass fiber may be formed by twisting glass filaments including silica to thereby form yarns and weaving the yarns.

The glass filament of the central reinforcement material may have a diameter larger by 2 μm to 5 μm than those of the glass filaments of the remaining other reinforcement materials.

The plurality of reinforcement materials may be formed in three-layers of the central reinforcement material, an upper reinforcement material formed at an upper portion of the central reinforcement material, and a lower reinforcement material formed at a lower portion of the central reinforcement material, and the thickness of the central reinforcement material may be thicker than those of the upper reinforcement material and the lower reinforcement material.

The thickness of the central reinforcement material may be thicker by 10 μm to 30 μm than those of the upper reinforcement material and the lower reinforcement material.

Each of the central reinforcement material, the upper reinforcement material, and the lower reinforcement material may be at least one selected from a group consisting of paper, glass fiber, glass nonwoven fabric, aramid fiber, liquid crystal polymer fiber, liquid crystal polymer nonwoven fabric, and hybrid fiber.

The glass fiber may be formed by twisting glass filaments including silica to thereby form yarns and weaving the yarns.

The glass filament of the central reinforcement material may have a diameter larger by 2 μm to 5 μm than those of the glass filaments of the upper reinforcement material and the lower reinforcement material. The via may have a sandglass shape.

### BRIEF DESCRIPTION OF THE DRAWINGS

FIG. 1 is a photograph showing an inner via hole having a sandglass shape;

FIG. 2 is a photograph showing a shape of the inner via hole depending on positions, thickness deviation, and the like of reinforcement materials formed in an insulating substrate;

FIG. 3 is a photograph showing an inner via hole in which fill plating defect is caused;

FIG. 4 is a cross-sectional view schematically showing an insulating substrate for a printed circuit board according to an exemplary embodiment of the present invention;

FIG. 5 is a view for describing a structure of glass fiber;

FIG. 6 is a view showing an institute for interconnecting and packaging electronic circuit (IPC) standard specification for the glass fiber;

FIG. 7 is an enlarged view of a structure of a representative glass fiber among glass fibers according to IPC names in FIG. 6;

FIG. 8 is a cross-sectional view schematically showing an insulating substrate for a printed circuit board according to a modified example of the present invention;

FIG. 9 is a cross-sectional view schematically showing a printed circuit board according to an exemplary embodiment of the present invention; and

FIGS. 10 and 11 are cross-sectional views schematically showing a printed circuit board according to a comparative example of the present invention.

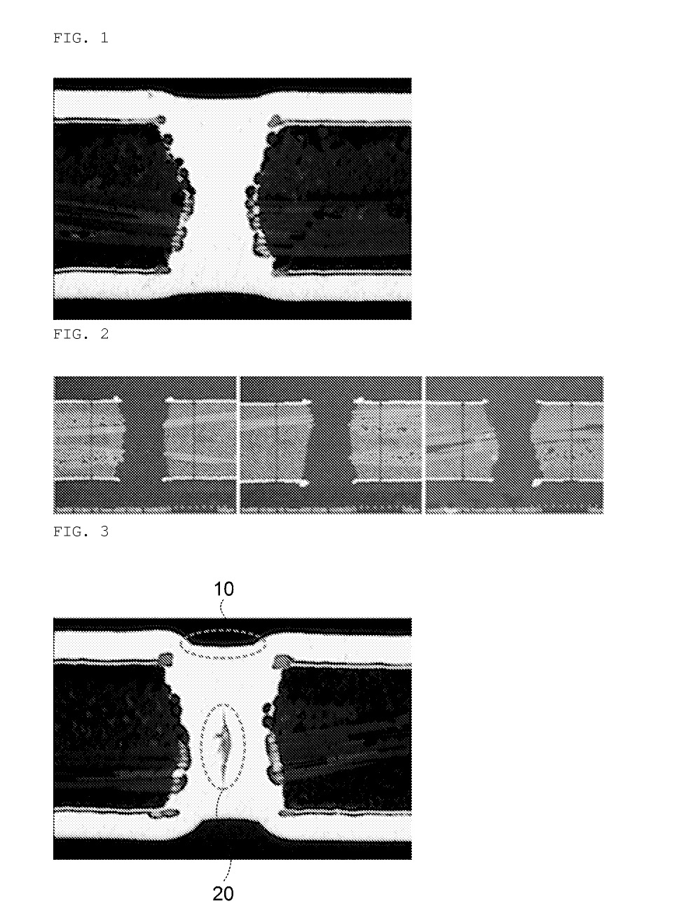

### DESCRIPTION OF THE PREFERRED EMBODIMENTS

The acting effects and technical configuration with respect to the objects of an insulating substrate for a printed circuit board and a printed circuit board according to the present invention will be clearly understood by the following description in which exemplary embodiments of the present invention are described with reference to the accompanying drawings.

Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

Insulating Substrate for Printed Circuit Board

### Embodiment

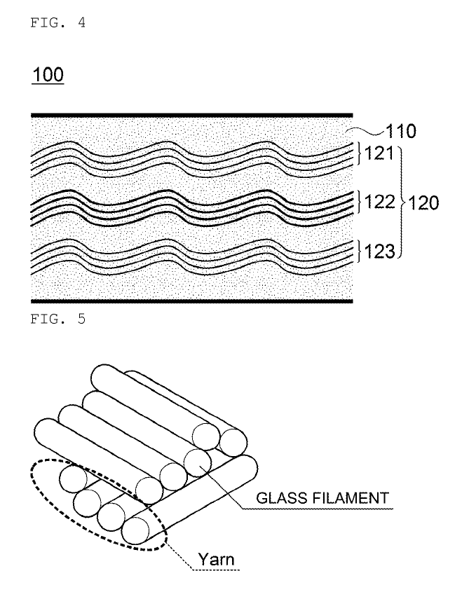

FIG. 4 is a cross-sectional view schematically showing an insulating substrate 100 for a printed circuit board according to an exemplary embodiment of the present invention.

As shown in FIG. 4, the insulating substrate 100 for the printed circuit board according to the present exemplary embodiment may be configured to include an electrical insulating resin 110 and a plurality of reinforcement materials 120. In this case, a copper clad laminate (CCL) in which copper foil is laminated on both surfaces thereof may be used as an example of the insulating substrate 100, but the present invention is not particularly limited thereto.

First, the electrical insulating resin 110, which has electrical insulating characteristics, may be at least one selected from a group consisting of a thermo-setting resin, a thermo-plastic resin, and a mixed resin thereof as a specific example, but is not particularly limited thereto.

In this case, the thermo-setting resin may be at least one selected from a group consisting of an epoxy resin, a phenolic resin, an epoxy acrylate resin, a melamine resin, a polyphenylene ether resin, a polyether sulfone resin, a polyether ether ketone resin, a polyphenylene sulfide resin, a polyphenylene ether resin, a polyphenylene oxide resin, a polyimide resin, a polyamide imide resin, a polyether imide resin, a polysulfone resin, a polyether sulfone resin, a polyketone resin, a polyether ketone resin, a polyether ether ketone resin, a fluorine resin, a polyurethane based resin, polyisoprene resin, copolymer resins thereof, modified resins thereof, and mixtures thereof, but is not particularly limited thereto.

In addition, the thermo-plastic resin may be at least one selected from a group consisting of polyethylene terephthalate (PET), polybutylene terephthalate (PBT), polytrimethylene terephthalate, polyethylene naphthalate, polyethylene, polypropylene, a styrene based resin, a polyoxymethylene resin, a polyamide resin, a polycarbonate resin, a polymethyl methacrylate resin, a polyvinyl chloride resin, copolymer resins thereof, modified resins thereof, and mixtures thereof, but is not particularly limited thereto.

In addition, as the electrical insulating resin 110, a mixed resin in which the thermo-setting resins and the thermo-plastic resins as mentioned above are mixed may be used.

In the present exemplary embodiment, as the electrical resin 10, an epoxy based resins such as FR-4, bismaleimide triazine (BT), an ajinomoto build up film (ABF), and the like may be used, but the present invention is not particularly limited thereto.

Next, the reinforcement material 120 may increase strength in perpendicular and horizontal directions of the electrical insulating resin 110 and decrease a dimensional change due to a temperature (a coefficient of thermal expansion). As shown in FIG. 4, a plurality of layers 121, 122, and 123 may be formed in the electrical insulating resin 110.

In the plurality of reinforcement materials according to the present invention, one or more reinforcement materials may be formed to be symmetrical with each other on upper and lower portions, respectively, based on a central reinforcement material formed at a central portion in the electrical insulating resin. In the present exemplary embodiment, as shown in FIG. 4, each of the reinforcement materials, that is, an upper reinforcement material 121 and a lower reinforcement material 123 may be formed to be symmetrical with each other at the upper and lower portions based on the central reinforcement material 122.

That is, the reinforcement material 120 according to the present embodiment may be formed in three layers of the upper reinforcement material 121, the central reinforcement material 122, and the lower reinforcement material 123, as shown in FIG. 4.

In this case, the upper reinforce material 121 is formed at an upper portion of the central reinforcement material 122, the lower reinforcement material 123 is formed at a lower portion of the central reinforcement material 122, and the upper and lower reinforcement materials 121 and 123 may be formed to be symmetrical with each other based on the central reinforcement material 122, as shown in FIG. 4.

In addition, the plurality of reinforcement materials according to the present invention may allow a thickness of the central reinforcement material to be thicker than those of the remaining other reinforcement materials. Particularly, the thickness of the central reinforcement material may be thicker by 10 μm to 30 μm than those of the remaining other reinforcement materials.

That is, in the present exemplary embodiment, as shown in FIG. 4, the thickness of the central reinforcement material 122 may be thicker than those of the upper and lower reinforcement materials 121 and 123. Particularly, the thickness of the central reinforcement material 122 may be thicker by 10 μm to 30 μm than those of the upper and lower reinforcement materials 121 and 123.

In the present exemplary embodiment, as described above, the plurality of reinforcement materials are formed in the insulating substrate, one or more reinforcement materials are formed to be symmetrical with each other at each of the upper and lower portions based on a reinforcement material of the central portion (that is, the upper and lower reinforcement materials are formed to be symmetrical with each other at each of the upper and lower portions based on the central reinforcement material), and the thickness of the reinforcement material of the central portion is formed to be thicker than those of the remaining reinforcement materials (that is, the thickness of the central reinforcement material is formed to be thicker than that of the upper and lower reinforcement materials), such that machinability by laser or the like for the central portion of the insulating substrate may be relatively decreased as compared to the remaining portions.

Therefore, in a process of forming a hole in the printed circuit board, in the case in which the insulating substrate according to the present exemplary embodiment is used, the inner via hole having the sandglass shape may be naturally formed by the machining such as a laser, thereby further improving fill plating property of the inner via hole.

In addition, each of the plurality of reinforcement materials according to the present invention may be at least one selected from a group consisting of paper, glass fiber, glass nonwoven fabric, aramid fiber, and hybrid fiber. In the present exemplary embodiment, as shown in FIG. 4, the upper reinforcement material 121, each of the central reinforcement material 122, and the lower reinforcement material 123 may be at least one selected from a group consisting of paper, glass fiber, glass nonwoven fabric, aramid fiber, the hybrid fiber. However, the present invention is not limited thereto, and may use any kind of materials as long as the material may give characteristics such as an increase in strength, low thermal expansion, and the like of the electrical insulating resin.

In this case, the paper is the reinforcement material having good penetrability into the resin, inexpensive price, and excellent punching machinability. Craft paper manufactured from broadleaf tree as a raw material is mainly used, but the present invention is not particularly limited thereto.

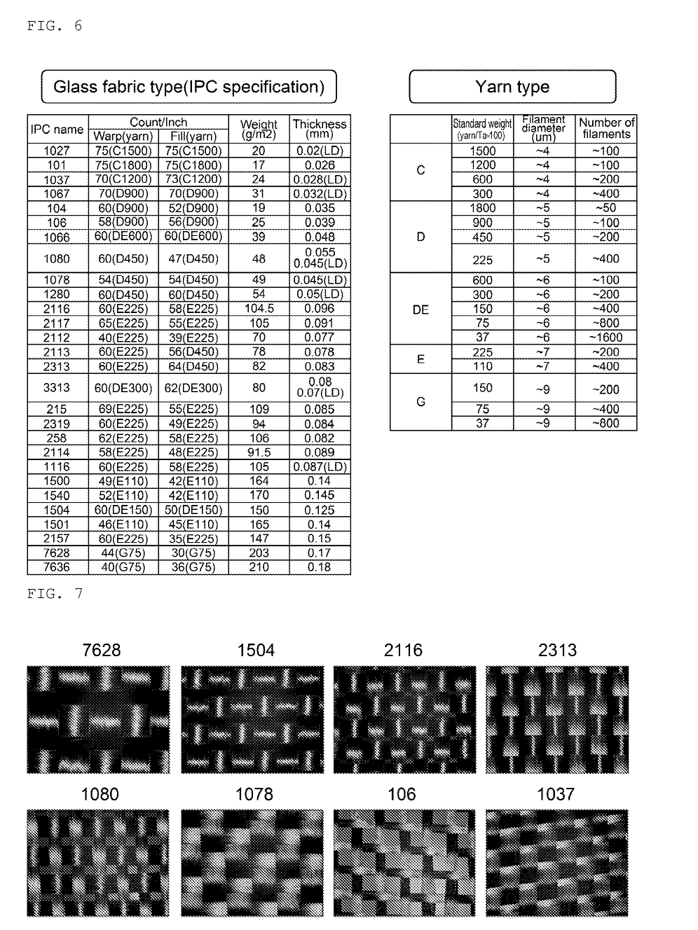

FIG. 5 shows a view for describing a structure of glass fiber, where the glass fiber may be formed by twisting several tens to several hundreds or more of glass filaments having silica as a main component to manufacture yarns as shown in FIG. 5 and weaving the yarns. The glass fiber having the structure as described above may have excellent thermal resistance, mechanical strength, and electrical insulation.

In addition, the glass nonwoven fabric, in which the glass fiber becomes a paper state, has excellent punching and drill machinability, and the hybrid fiber, which is a fiber reinforcement material of an advanced composite material, includes fiber such as aramid, silicone, boron, alumina, and the like as well as carbon fiber having high strength and high modulus of elasticity.

Further, the aramid fiber, which has 5 times higher strength than a steel having the same weight, is a strongest material among existing fibers, and is a high functional material having excellent thermal resistance which is unburned even at 500° C. and chemical resistance to chemical agents. In addition, the aramid fiber may be light, not be easily worn, and be conveniently machined as compared to a metal or an inorganic material. Therefore, the aramid fiber is well used as a high density and multi-layer reinforcement material. In addition to this, the aramid fiber has been used in various industry fields such as a high performance tire, a hose, a belt, an optical cable reinforcement material, a body armour, a bombproof helmet, a brake's friction material, a gasket sealing material, and the like.

As mentioned above, each of the plurality of reinforcement materials 120 according to the present exemplary embodiment may be the glass fiber having a structure as shown in FIG. 5. A standard specification for the glass fiber is already defined by the institute for interconnecting and packaging electronic circuit (IPC), that is, an international organization defining a standard specification for product and assembly of a PCB, a connector, a cable, a package, and the like.

FIG. 6 is a view showing an IPC standard specification for the glass fiber and FIG. 7 is an enlarged view of a structure of a representative glass fiber among glass fibers according to IPC names in FIG. 6.

In this case, FIG. 6 also shows an IPC standard specification for glass filament diameters in the glass fiber. The glass fiber matching the IPC standard specification mentioned above may be used as the reinforcement material according to the present invention.

In this case, as mentioned above, since it is preferable to allow the thickness of the central reinforcement material to be thicker by 10 μm to 30 μm than those of the remaining other reinforcement materials, it is preferable to allow a glass filament diameter of the central reinforcement material to be larger by 2 μm to 5 μm than those of the remaining other reinforcement materials.

That is, again back to FIG. 4, in the present exemplary embodiment, it is preferable to allow the thickness of the central reinforcement material 122 to be thicker by 10 μm to 30 μm than those of the upper and lower reinforcement materials 121 and 123. As a result, it is preferable to allow a glass filament diameter of the central reinforcement material 122 to be larger by 2 μm to 5 μm than those of the upper and lower reinforcement materials 121 and 123.

### MODIFIED EXAMPLE

FIG. 8 is a cross-sectional view schematically showing an insulating substrate 200 for a printed circuit board according to a modified example of the present invention.

As shown in FIG. 8, the insulating substrate 200 for the printed circuit board according to the modified example of the present invention may be configured to include an electrical insulating resin 210 and a plurality of reinforcement materials 220, similar to the exemplary embodiment in FIG. 4. In this case, a copper clad laminate (CCL) in which copper foil is laminated on both surfaces thereof may be used as an example of the insulating substrate 200 similar to the exemplary embodiment in FIG. 4, but the present invention is not particularly limited thereto.

Since configurations and characteristics of the electrical insulating resin 210 according to the modified example are overlapped with those of the electrical insulating resin 110 according to the exemplary embodiment in FIG. 4, a detailed description thereof will be omitted. Therefore, the plurality of reinforcement materials 220 will be mainly described below.

The reinforcement material 220 shown in FIG. 8 is a modified example of the reinforcement material 120 according to the exemplary embodiment in FIG. 4. As shown in FIG. 8, two reinforcement materials, that is, first and second upper reinforcement materials 221 and 222 and first and second lower reinforcement materials 224 and 225 may be formed to be symmetrical with each other on upper and lower portions based on a central reinforcement material 223.

The reinforcement material 220 according to the modified example may be formed in five layers of the first upper reinforcement material 221, the second upper reinforcement material 222, the central reinforcement material 223, the first lower reinforcement material 224, and the second lower reinforcement material 225, unlike the reinforcement material in FIG. 4 formed in the three layers of the upper reinforcement material, the central reinforcement material, and the lower reinforcement material.

In this case, the first upper reinforcement material 221 is formed at an upper portion of the second upper reinforcement material 222, and the second upper reinforcement material 222 is formed at an upper portion of the central reinforcement material 223.

In addition, the first lower reinforcement material 224 is formed at a lower portion of the central reinforcement material 223, and the second lower reinforcement material 225 is formed at a lower portion of the first lower reinforcement material 224.

In this case, the first and second upper materials 221 and 222 and the first and second lower reinforcement materials 224 and 225 may be formed to be symmetrical with each other based on the central reinforcement material 223 as shown in FIG. 8.

In addition, the plurality of reinforcement materials according to the present invention may allow a thickness of the central reinforcement material to be thicker than those of the remaining other reinforcement materials. Particularly, the thickness of the central reinforcement material may be thicker by 10 μm to 30 μm than those of the remaining other reinforcement materials.

That is, the reinforcement material 220 according to the modified example, which is a modified example of the reinforcement material according to the exemplary embodiment in FIG. 4, may allow a thickness of the central reinforcement material 223 to be thicker than those of the first and second upper materials 221 and 222 and the first and second lower reinforcement materials 224 and 225. Particularly, the thickness of the central reinforcement material 223 may be thicker by 10 μm to 30 μm than those of the first and second upper materials 221 and 222 and the first and second lower reinforcement materials 224 and 225.

Meanwhile, each of the plurality of reinforcement materials according to the present invention may be at least one selected from a group consisting of paper, glass fiber, glass nonwoven fabric, aramid fiber, and hybrid fiber, for example. In the reinforcement material 220 according to the modified example, as shown in FIG. 8, each of the first upper reinforcement material 221, the second upper reinforcement material 222, the central reinforcement material 223, the first lower reinforcement material 224, and the second lower reinforcement material 225 may be at least one selected from a group consisting of the paper, the glass fiber, the glass fabric, the aramid fiber, and the hybrid fiber. However, the present invention is not limited thereto, and may use any kind of materials as long as the material may give characteristics such as an increase in hardness, low thermal expansion, and the like of the electrical insulating resin.

Since a description of the paper, the glass fiber, the glass nonwoven fabric, the aramid fiber, and the hybrid fiber capable of forming each of the plurality of reinforcement materials 220 is overlapped with that of the plurality of reinforcement materials 120 according to the exemplary embodiment in FIG. 4, a detailed description thereof will be omitted.

Meanwhile, each of the plurality of reinforcement materials 220 according to the modified example may be the glass fiber having the structure as shown in FIG. 5, similar to the plurality of reinforcement materials 120 according to the exemplary embodiment in FIG. 4. Therefore, the glass fiber matching the IPC standard specification may be used as the reinforcement material similar to the reinforcement material 120 in FIG. 4.

Therefore, in this case, also in the plurality of reinforcement materials 220 similar to the plurality of reinforcement materials 120 according to the exemplary embodiment in FIG. 4, since it is preferable to allow the thickness of the central reinforcement material to be thicker by 10 μm to 30 μm than those of the remaining other reinforcement materials, it is preferable to allow a glass filament diameter of the central reinforcement material to be larger by 2 μm to 5 μm than those of the remaining other reinforcement materials.

That is, again back to FIG. 8, in the modified example, it is preferable to allow the thickness of the central reinforcement material 223 to be thicker by 10 μm to 30 μm than those of the first and second upper materials 221 and 222 and the first and second lower reinforcement materials 224 and 225. As a result, it is preferable to allow a glass filament diameter of the central reinforcement material 223 to be larger by 2 μm to 5 μm than those of the first and second upper reinforcement materials 221 and 222 and the first and second lower reinforcement materials 224 and 225.

In the modified example, similar to the exemplary embodiment in FIG. 4, a configuration in which the plurality of reinforcement materials are formed in the insulating substrate, one or more reinforcement materials are formed to be symmetrical with each other at each of the upper and lower portions based on a reinforcement material of the central portion (that is, the first and second upper reinforcement materials and the first and second lower reinforcement materials are formed to be symmetrical with each other at each of the upper and lower portions based on the central reinforcement material), and the thickness of the reinforcement material of the central portion is formed to be thicker than those of the remaining reinforcement materials (that is, the thickness of the central reinforcement material is formed to be thicker than those of the first and second upper materials and the first and second lower reinforcement materials) is used, such that machinability of a laser or the like for the central portion of the insulating substrate 200 may be relatively decreased as compared to the remaining portions.

Therefore, in a process of forming a hole in the printed circuit board, in the case in which the insulating substrate according to the modified example is used, similar to the exemplary embodiment in FIG. 4, the inner via hole having the sandglass shape may be naturally formed by the machining such as laser, thereby further improving fill plating property of the inner via hole.

Meanwhile, the present invention is not limited to the exemplary embodiment and the modified example as described above, but may be implemented in various modified examples without departing from the essential characteristics of the present invention.

That is, the insulating substrate according to the present invention may be implemented in various modified examples having the plurality of reinforcement materials in which one or more reinforcement materials are formed to be symmetrical with each other at each of the upper and lower portions based on the central reinforcement material formed at the central portion in the electrical insulating resin, and the thickness of the central reinforcement material is thicker than those of the remaining other reinforcement materials on the upper and lower portions (for example, various modified examples having a reinforcement material having odd layers of seven layers or more in which one or more reinforcement materials are formed to be symmetrical with each other at each of the upper and lower portions based on the central reinforcement material formed at the central portion and the thickness of the central reinforcement material is thicker than those of the upper and lower reinforcement materials, in addition to the exemplary embodiment and the modified example as described above).

Printed Circuit Board

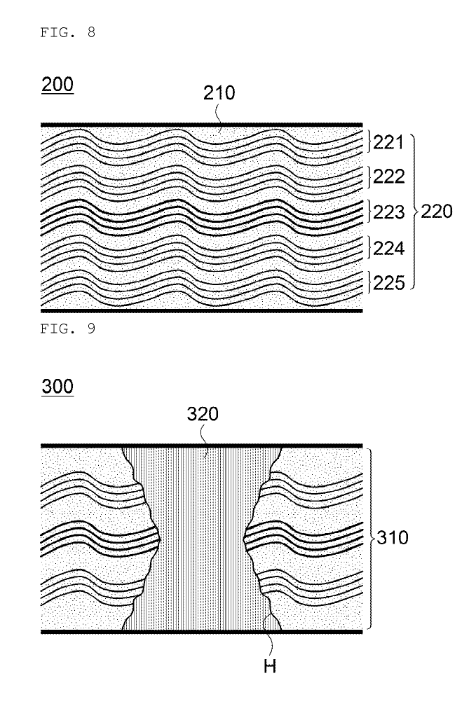

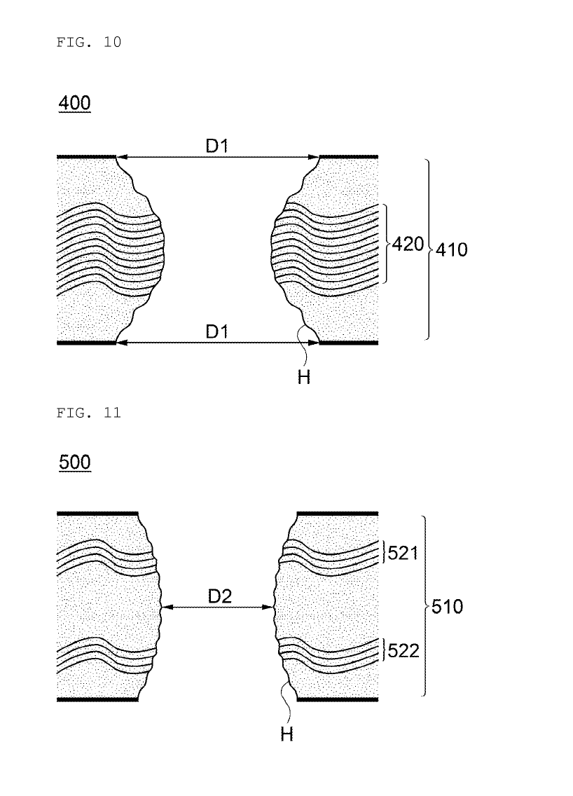

FIG. 9 is a cross-sectional view schematically showing a printed circuit board 300 according to an exemplary embodiment of the present invention.

Referring to FIG. 9, the printed circuit board 300 according to the present exemplary embodiment may be formed to include an insulating substrate 310 and a via 320.

As the insulating substrate 310 according to the present exemplary embodiment, the insulating substrate for the printed circuit board according to the exemplary embodiment or various modified example of the present invention may be used, and since the configuration thereof is overlapped with the description describe above, a detailed description thereof will be omitted.

In addition, the via 320 according to the present exemplary embodiment, which is to electrically connect between the layers in order to improve electrical characteristics and a degree of freedom of a design, may be formed so as to be penetrated through the insulating substrate 310 as shown in FIG. 9.

In this case, the via 320 may be formed by forming a via hole H formed so as to be penetrated through the insulating substrate 310 and then performing fill plating, or the like on an inner wall of the via hole H.

The via hole H may be formed by drilling machining, laser machining, or the like using a CNC device, or the like. Particularly, in the case in which the via hole H is formed by the laser machining, laser using CO₂, YAG laser, or the like may be used.

In this case, when the via hole is formed on the insulating substrate 310 according to the present exemplary embodiment, that is, the insulating substrate in which the plurality of reinforcement materials are formed, one or more reinforcement materials are formed to be symmetrical with each other at each of the upper and lower portions based on the reinforcement material at the central portion, the reinforcement material at the central portion is formed so as to have the thickness thicker than the remaining reinforcement materials, machinability by a laser for the central portion of the insulating substrate may be relatively decreased as compared to the remaining portions.

Therefore, in a process of forming the via hole in the printed circuit board, in the case in which the insulating substrate according to the present invention is used, the inner via hole H having the sandglass shape as shown in FIG. 9 may be naturally formed by the machining such as a laser, or the like, thereby further improving fill plating property of the inner via hole H.

On the other hand, unlike the present invention, in a case of forming the inner via hole using the insulating substrate having a form in which the reinforcement material is formed only at the central portion and is not formed at the upper and lower portions (see FIG. 10) or a form in which the reinforcement materials are formed to be symmetrical with each other only at the upper and lower portions and are not formed at the central portion (see FIG. 11), fill plating defects such as a dimple, a void, and the like may be caused.

FIGS. 10 and 11 are cross-sectional views schematically showing a printed circuit board according to a comparative example of the present invention. The content described above will be described in more detail with reference to FIGS. 10 and 11.

First, in a case of an insulating substrate 410 used in a printed circuit board 400 in FIG. 10, unlike the present invention, a reinforcement material 420 is formed only at the central portion and is not formed at upper and lower regions of the insulating substrate. Therefore, in the case in which the inner via hole H is formed in the above-mentioned insulating substrate 410 using laser, or the like, even though the same laser machining condition (as an example, CO₂ laser machining condition, or the like) as the present invention is applied, diameters D1 of upper and lower portions of the inner via hole which is formed significantly become wider as compared to the present invention. Therefore, in a case of the inner via hole H formed in the insulating substrate 410 as in FIG. 10, fill plating defects such as a dimple, a void, and the like are intensively caused.

In addition, in a case of an insulating substrate 510 used in a printed circuit board 500 in FIG. 11, since reinforcement materials 521 and 522 are formed to be symmetrical with each other at the upper and lower regions, the diameters of the inner via hole H do not become wider as compared to the insulating substrate in FIG. 10. However, unlike the present invention, since the reinforcement material is not formed at the central region, in the case in which the inner via hole is formed in the insulating substrate 510 as in FIG. 11 using a laser, or the like, even though the same laser machining condition (as an example, CO₂ laser machining condition, or the like) as the present invention is applied, diameters D2 of the central portion of the inner via hole which is formed significantly become wider as compared to the present invention. Therefore, in a case of the inner via hole H formed in the insulating substrate 510 as in FIG. 11, possibility that fill plating defects such as a void, and the like are caused at, particularly, the central portion is significantly increased as compared to the present invention.

Meanwhile, again back to FIG. 9, once the via hole H is formed in the insulating substrate 310 by the process such as a laser, or the like, fill plating is performed on a surface of the insulating substrate 310 and in the via hole H by chemical copper, such that the via 320 having a plated layer formed in the via hole H may be formed.

In addition, in the case in which the via 320 is formed by forming the plated layer in the via hole H, the printed circuit board 300 according the present exemplary embodiment may further include a conductive layer (not shown) and a circuit pattern (not shown) formed on the surface of the insulating substrate 310 including an upper surface of the via hole H in which fill plating is completed, where the circuit pattern is electrically connected to the plated layer of the via 320.

According to the exemplary embodiments of the present invention, in the insulating substrate for the printed circuit board and the printed circuit board having the configuration as described above, the plurality of reinforcement materials are formed on the insulating substrate, one or more reinforcement materials are formed to be symmetrical with each other at each of the upper and lower portions based on the reinforcement material at the central portion, the reinforcement material at the central portion is formed so as to have the thickness thicker than the remaining reinforcement materials, thereby making it possible to relatively decrease machinability of the laser, or the like for the central portion of the insulating substrate as compared to the remaining portions.

Therefore, since the inner via hole having the sandglass shape may be naturally formed by the machining such as the laser, the fill plating property of the inner via hole may be further improved.

In the present specification, ‘an exemplary embodiment’ and other modified expressions mean that a certain feature, structure, or characteristic is included in at least one embodiment. Accordingly, the expression “an exemplary embodiment” and other modified examples in the present specification may not denote the same embodiment.

In the present specification, the expression “at least one of A and B” is used to include a selection of only A, only B, or both A and B. Furthermore, the expression “at least one of A through C” may be used to include a section of only A, only B, only C, only A and B, only B and C, or all of A through C. One of ordinary skill in the art would be able to clearly interpret a similar expression with more elements.

The exemplary embodiment of the present invention has been described above. While this inventive concept has been particularly shown and described with reference to exemplary embodiments thereof, it will be understood by those of ordinary skill in the art that various changes in form and details may be made therein without departing from the spirit and scope of the inventive concept as defined by the appended claims. The exemplary embodiments should be considered in a descriptive sense only and not for purposes of limitation. Therefore, the scope of the inventive concept is defined not by the detailed description but by the appended claims, and all differences within the scope will be construed as being included in the present inventive concept.

What is claimed is:

1. An insulating substrate for a printed circuit board, the insulating substrate comprising:
an electrical insulating resin; and
a plurality of reinforcement materials formed in the electrical insulating resin,
wherein the plurality of reinforcement materials are configured so that one or more reinforcement materials are formed to be symmetrical with each other at each of the upper and lower portions based on a central reinforcement material formed at a central portion in the electrical insulating resin, and a thickness of the central reinforcement material is thicker than those of the remaining other reinforcement materials.

2. The insulating substrate according to claim 1, wherein the thickness of the central reinforcement material is thicker by 10 μm to 30 μm than those of the remaining other reinforcement materials.

3. The insulating substrate according to claim 2, wherein each of the plurality of reinforcement materials is at least one selected from a group consisting of paper, glass fiber, glass nonwoven fabric, aramid fiber, liquid crystal polymer fiber, liquid crystal polymer nonwoven fabric, and hybrid fiber.

4. The insulating substrate according to claim 3, wherein the glass fiber is formed by twisting glass filaments including silica to thereby form yarns and weaving the yarns.

5. The insulating substrate according to claim 4, wherein the glass filament of the central reinforcement material has a diameter larger by 2 μm to 5 μm than those of the glass filaments of the remaining other reinforcement materials.

6. The insulating substrate according to claim 1, wherein the plurality of reinforcement materials are formed in three-layers of the central reinforcement material, an upper reinforcement material formed at an upper portion of the central reinforcement material, and a lower reinforcement material formed at a lower portion of the central reinforcement material, and
the thickness of the central reinforcement material is thicker than those of the upper reinforcement material and the lower reinforcement material.

7. The insulating substrate according to claim 6, wherein the thickness of the central reinforcement material is thicker by 10 μm to 30 μm than those of the upper reinforcement material and the lower reinforcement material.

8. The insulating substrate according to claim 7, wherein each of the central reinforcement material, the upper reinforcement material, and the lower reinforcement material is at least one selected from a group consisting of paper, glass fiber, glass nonwoven fabric, aramid fiber, liquid crystal polymer fiber, liquid crystal polymer nonwoven fabric, and hybrid fiber.

9. The insulating substrate according to claim 8, wherein the glass fiber is formed by twisting glass filaments including silica to thereby form yarns and weaving the yarns.

10. The insulating substrate according to claim 9, wherein the glass filament of the central reinforcement material has a diameter larger by 2 μm to 5 μm than those of the glass filaments of the upper reinforcement material and the lower reinforcement material.

11. A printed circuit board, comprising:
an insulating substrate; and
a via penetrating through the insulating substrate,
wherein the insulating substrate includes:
an electrical insulating resin; and
a plurality of reinforcement materials formed in the electrical insulating resin,
wherein the plurality of reinforcement materials are configured so that one or more reinforcement materials are formed to be symmetrical with each other at each of the upper and lower portions based on a central reinforcement material formed at a central portion in the electrical insulating resin, and a thickness of the central reinforcement material is thicker than those of the remaining other reinforcement materials.

12. The printed circuit board according to claim 11, wherein the thickness of the central reinforcement material is thicker by 10 μm to 30 μm than those of the remaining other reinforcement materials.

13. The printed circuit board according to claim 12, wherein each of the plurality of reinforcement materials is at least one selected from a group consisting of paper, glass fiber, glass nonwoven fabric, aramid fiber, liquid crystal polymer fiber, liquid crystal polymer nonwoven fabric, and hybrid fiber.

14. The printed circuit board according to claim 13, wherein the glass fiber is formed by twisting glass filaments including silica to thereby form yarns and weaving the yarns.

15. The printed circuit board according to claim 14, wherein the glass filament of the central reinforcement material has a diameter larger by 2 μm to 5 μm than those of the glass filaments of the remaining other reinforcement materials.

16. The printed circuit board according to claim 11, wherein the plurality of reinforcement materials are formed in three-layers of the central reinforcement material, an upper reinforcement material formed at an upper portion of the central reinforcement material, and a lower reinforcement material formed at a lower portion of the central reinforcement material, and
the thickness of the central reinforcement material is thicker than those of the upper reinforcement material and the lower reinforcement material.

17. The printed circuit board according to claim 16, wherein the thickness of the central reinforcement material is thicker by 10 μm to 30 μm than those of the upper reinforcement material and the lower reinforcement material.

18. The printed circuit board according to claim 17, wherein each of the central reinforcement material, the upper reinforcement material, and the lower reinforcement material is at least one selected from a group consisting of paper, glass fiber, glass nonwoven fabric, aramid fiber, liquid crystal polymer fiber, liquid crystal polymer nonwoven fabric, and hybrid fiber.

19. The printed circuit board according to claim 18, wherein the glass fiber is formed by twisting glass filaments including silica to thereby form yarns and weaving the yarns.

20. The printed circuit board according to claim 19, wherein the glass filament of the central reinforcement material has a diameter larger by 2 μm to 5 μm than those of the glass filaments of the upper reinforcement material and the lower reinforcement material.

21. The printed circuit board according to claim 11, wherein the via has a sandglass shape.
